(19) United States
(12) Patent Application Publication
(10) Pub. No.: US 2008/0149274 A1
(43) Pub. Date: Jun. 26, 2008

(54) PLASMA PROCESSING APPARATUS

(75) Inventor: Nobumasa Suzuki, Yokohama-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 11/871,839

(22) Filed: Oct. 12, 2007

(30) Foreign Application Priority Data
Dec. 22, 2006 (JP) 2006-345795

(51) Int. Cl. C23C 16/00

(52) U.S. Cl. 156/345.41; 118/723 VE

(57) ABSTRACT

A plasma processing apparatus includes a vacuum vessel having a dielectric window; a first exhaust unit configured to evacuate the vacuum vessel; a microwave introducing portion for introducing a microwave into the vacuum vessel through the dielectric window; and a second exhaust unit configured to evacuate a closed space of the microwave introducing portion side of the dielectric window. Even when local stress is produced, the dielectric window is resistant to destruction. Even if the dielectric window is broken, the vacuum vessel is not significantly damaged.

### BACKGROUND OF THE INVENTION

1. Field of the Invention

The present invention relates to a plasma processing apparatus that utilizes a microwave as an excitation source.

2. Description of the Related Art

In recent years, a processing plasma technology has been becoming more important to satisfy the demands for low-temperature processes for manufacturing various electronic devices. Among others, plasma utilizing a microwave as an excitation source can have a density as high as 10¹² cm⁻³ or more and an electron temperature as low as 1 eV or less. A microwave is an electromagnetic wave having a frequency higher than that of a radiofrequency wave. The microwave plasma results in less damage, realizes high-quality and high-speed processing, and has a lot of future potential. Microwave plasma processing apparatuses are practically used in chemical vapor deposition (CVD), etching, ashing, nitriding, oxidation, and cleaning.

A plasma processing apparatus that utilizes a microwave as a source for exciting a processing gas can accelerate electrons in a high-frequency electric field and thereby efficiently excite, ionize, and decompose gas molecules. Thus, the microwave plasma can easily form high-density plasma and allows for low-temperature and high-speed processing. Furthermore, because the high-density plasma has a density beyond the cutoff density, a microwave electric field cannot penetrate into the bulk plasma. This reduces the electron temperature, results in less damage, and allows for high-quality processing. In addition, because a microwave can pass through a dielectric material, a plasma processing apparatus can be of the electrodeless discharge type. This reduces metal contamination and allows for clean plasma processing.

As an example of a microwave plasma processing apparatus, in Japanese Patent Laid-Open No. 2000-138171, the present inventors proposed an apparatus that includes a circular waveguide as a uniform and efficient microwave introducing portion, in which a plurality of arcuate slots are disposed on an H-plane. FIG. 3 is a schematic view of this microwave plasma processing apparatus. FIGS. 4A-B illustrate a plasma generation mechanism of this apparatus.

Referring to FIGS. 3 and 4A-B, the microwave plasma processing apparatus includes a plasma processing chamber 301, a substrate 302 to be treated, a supporting portion 303 for supporting the substrate 302, a substrate temperature regulator 304, plasma processing gas inlets 305 disposed around the plasma processing chamber 301, an exhaust port 306, a planar dielectric window 307, which separates the plasma processing chamber 301 from the atmosphere, a circular waveguide multislot antenna 308 for introducing a microwave into the plasma processing chamber 301 through the dielectric window 307, a circular waveguide 312, an E branch 311 for introducing a microwave into the circular waveguide 312, and arcuate slots 314. Surface waves 315 propagate over the surface of the dielectric window 307. Surface waves from adjacent slots interfere with each other to form surface standing waves 316. The surface standing waves 316 generate plasma 317. The plasma 317 diffuses to form a plasma bulk 318.

Plasma processing is performed as described below. Place the substrate 302 to be treated on the substrate supporting portion 303. Evacuate the plasma processing chamber 301 using an evacuation system (not shown) through the exhaust port 306. Introduce a processing gas at a predetermined flow rate into the plasma processing chamber 301 through the processing gas inlets 305 disposed around the plasma processing chamber 301. Control a conductance valve (not shown) of the evacuation system (not shown) to maintain a predetermined internal pressure of the plasma processing chamber 301. Transmit microwaves having a desired electric power from a microwave power supply (not shown) to the plasma processing chamber 301 via the circular waveguide 312. Microwaves transmitted to the circular waveguide 312 are divided at the E branch 311 into left and right halves, and interfere with each other in the circular waveguide 312, forming standing wave “antinodes” every half of the guide wavelength. Microwaves are introduced into the plasma processing chamber 301 through the arcuate slots 314 disposed at positions at which the surface current is maximum between the standing wave antinodes and also through the dielectric window 307, and generate plasma in the plasma processing chamber 301.

When the electron density of plasma exceeds the cutoff density, more specifically a threshold density for the generation of a surface-wave mode, microwaves incident on an interface between the dielectric window 307 and the plasma cannot propagate into the plasma, but propagate as surface waves 315 over the surface of the dielectric window 307. For a microwave having a frequency of 2.45 GHz, for example, the cutoff density is 7.5×10¹⁰ cm⁻³. For a quartz window, for example, the threshold density for the generation of a surface-wave mode is 3.4×10¹¹ cm⁻³. Surface waves 315 passing through adjacent slots interfere with each other and thereby form surface standing waves 316 having antinodes every half of the wavelength of the surface waves 315. Surface standing waves 316 localized in the vicinity of the surface of the dielectric window 307 generate plasma 317 having a very high density and a high electron temperature in the vicinity of the dielectric window 307. The plasma 317 diffuses toward the substrate 302 to be treated, is relaxed, and forms a plasma bulk 318 in the vicinity of the substrate 302. The plasma bulk 318 has a high density and a low electron temperature. The high-density plasma excites the processing gas. The surface of the substrate 302 disposed on the substrate supporting portion 303 is treated with the processing gas.

Such a microwave plasma processing apparatus can generate uniform, high density, and low electron temperature plasma. For a microwave power of at least 1 kW, the high density and low electron temperature plasma can have an electron density of at least 10¹¹ cm⁻³, an electron temperature of 1.5 eV or less, and a plasma potential of 7 V or less in a space having a large diameter of about 300 mm. The electron density, the electron temperature, and the plasma potential can be controlled with an accuracy of ±5%. Thus, a sufficiently activated processing gas can be applied to the substrate. Furthermore, incident ions cause less damage on the substrate surface. These permit uniform and high-speed processing even at low temperatures.

However, in the microwave plasma processing apparatus described above, destruction of the dielectric window sometimes causes serious damage to the vacuum equipment. According to the findings of the present inventor, the destruction occurs in cases where, in addition to the force of atmospheric pressure under normal conditions, local stress due to temperature variations caused by unknown factors is applied to the dielectric window.

### SUMMARY OF THE INVENTION

The present invention provides a plasma processing apparatus including a dielectric window resistant to local stress and a vacuum vessel resistant to damage even when the dielectric window is broken.

A plasma processing apparatus according to the present invention includes a vacuum vessel having a dielectric window, a first exhaust unit configured to evacuate the vacuum vessel, a microwave introducing portion for introducing a microwave into the vacuum vessel through the dielectric window, and a second exhaust unit configured to evacuate a closed space of the microwave introducing portion.

The present invention can provide a plasma processing apparatus including a dielectric window resistant to destruction and a vacuum vessel resistant to damage even when the dielectric window is broken.

A plasma processing apparatus according to the present invention includes a vacuum vessel having a dielectric window, a first exhaust unit configured to evacuate the vacuum vessel, a microwave introducing portion for introducing a microwave into the vacuum vessel, and a second exhaust unit configured to evacuate the microwave introducing portion. The microwave introducing portion is maintained under vacuum. This imparts resistance to local stress to the dielectric window. Even if the dielectric window is broken, the vacuum vessel is not significantly damaged.

Further features and aspects of the present invention will become apparent from the following description of exemplary embodiments with reference to the attached drawings.

### BRIEF DESCRIPTION OF THE DRAWINGS

FIG. 1 is a schematic view of a microwave plasma processing apparatus according to an exemplary embodiment of the present invention.

FIG. 2 shows pressure-dependency of the discharge starting power in the apparatus illustrated in FIG. 1.

FIG. 3 is a schematic view of a known microwave plasma processing apparatus.

FIGS. 4A and 4B are schematic views illustrating a mechanism of plasma generation of the apparatus illustrated in FIG. 3.

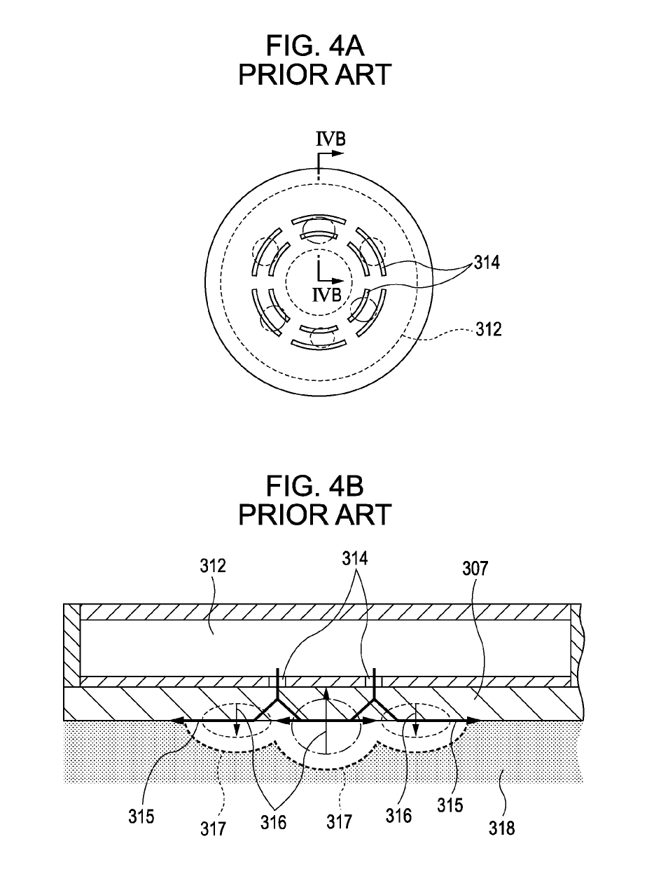

### DESCRIPTION OF THE EMBODIMENTS

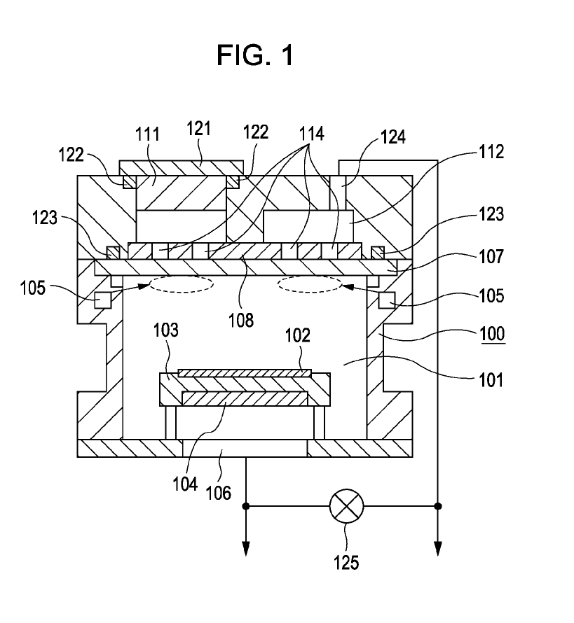

A microwave plasma processing apparatus according to an exemplary embodiment of the present invention will be described below with reference to FIG. 1. The microwave plasma processing apparatus includes a vacuum vessel 100, a plasma processing chamber 101, a substrate 102 to be treated, a supporting portion 103 for supporting the substrate 102, a substrate temperature regulator 104, a plasma processing gas inlets 105 disposed around the plasma processing chamber 101, a chamber exhaust port 106, and a dielectric window 107, which separates the plasma processing chamber 101 from a microwave introducing portion.

The microwave introducing portion includes a circular waveguide multislot antenna 108 for introducing a microwave into the plasma processing chamber 101 through the dielectric window 107, an E branch 111 for dividing microwaves into left and right halves, a circular waveguide 112, arcuate slots 114, an inlet window 121 disposed at a microwave inlet, a first sealant 122 for vacuum-sealing the inlet window 121, a second sealant 123 for vacuum-sealing a contact portion between the dielectric window 107 and the microwave introducing portion (the circular waveguide multislot antenna 108 and the circular waveguide 112), a waveguide exhaust port 124 from which a gas in the circular waveguide 112 is exhausted, and an equalizing valve 125. The equalizing valve 125 communicates the plasma processing chamber 101 with the circular waveguide 112.

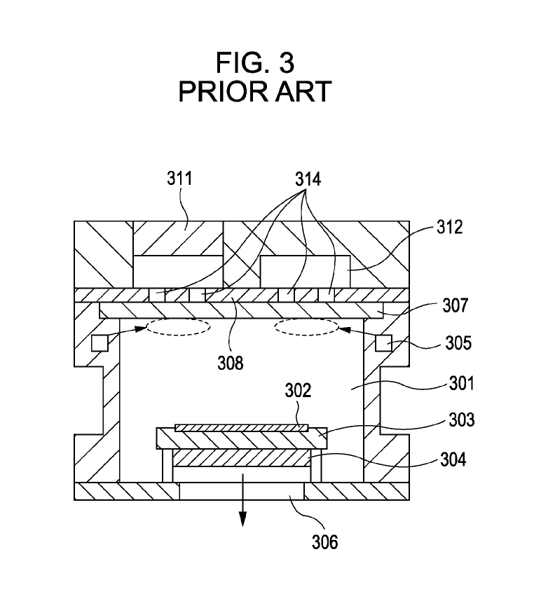

Thus, as compared with the known microwave plasma processing apparatus illustrated in FIG. 3, the apparatus illustrated in FIG. 1 further includes the inlet window 121, the first sealant 122, the second sealant 123, the waveguide exhaust port 124, and the equalizing valve 125. The inlet window 121 and the first sealant 122 seal the microwave inlet of the microwave introducing portion. The second sealant 123 seals the contact portion between the microwave introducing portion and the dielectric window. Furthermore, the first sealant 122 and the second sealant 123 form a closed space of the microwave introducing portion.

Plasma processing is performed as described below. Place the substrate 102 to be treated on the substrate supporting portion 103. Open the equalizing valve 125. Evacuate the plasma processing chamber 101 through the chamber exhaust port 106, and the waveguide 108 through the waveguide exhaust port 124, using an evacuation system (not shown) while maintaining the pressures of the plasma processing chamber 101 and the waveguide 108 identical. When the pressures become sufficiently low, close the equalizing valve 125. Introduce a processing gas at a predetermined flow rate into the plasma processing chamber 101 through the processing gas inlets 105 disposed around the plasma processing chamber 101. Control a conductance valve (not shown) of a processing chamber evacuation system (not shown) to maintain a predetermined internal pressure of the plasma processing chamber 101.

Transmit microwaves having a desired electric power from a microwave power supply (not shown) to the plasma processing chamber 101 via the circular waveguide 112 and the arcuate slots 114. Microwaves transmitted to the circular waveguide 112 are divided at the E branch 111 into left and right halves, and propagate with a guide wavelength being larger than that in free space. Divided microwaves interfere with each other and form standing waves having “antinodes” every half of the guide wavelength. Microwaves are introduced into the plasma processing chamber 101 through the arcuate slots 114, which are disposed across the surface current, and through the dielectric window 107. The microwaves introduced into the plasma processing chamber 101 generate initial high-density plasma in the vicinity of the arcuate slots 114.

When the electron density of the initial high-density plasma exceeds the cutoff density, more specifically a threshold density for the generation of a surface-wave mode, microwaves incident on an interface between the dielectric window 107 and the initial high-density plasma cannot propagate into the initial high-density plasma, but propagate as surface waves 115 over the surface of the dielectric window 107. For a microwave having a frequency of 2.45 GHz, for example, the cutoff density is 7.5×10¹⁰ cm⁻³. For a quartz window, for example, the threshold density for the generation of a surface-wave mode is 3.4×10¹¹ cm⁻³.

Surface waves passing through a plurality of arcuate slots 114 interfere with each other and thereby form surface standing waves having “antinodes” every half of the wavelength of the surface waves. The surface standing waves generate plasma having a very high density and a high electron temperature at an outer-area and the central part of the plasma processing chamber 101. The plasma diffuses and is relaxed to form a plasma bulk having a high density and a low electron temperature. The plasma excites and decomposes the processing gas. The surface of the substrate 102 disposed on the substrate supporting portion 103 is treated with activated processing gas components.

Even when the temperature of the dielectric window 107 varies during processing, the dielectric window 107 is rarely broken in the absence of atmospheric pressure. Furthermore, even if the dielectric window 107 is broken, the dielectric window 107 and the components in the plasma processing chamber 101 are not significantly damaged by the atmosphere.

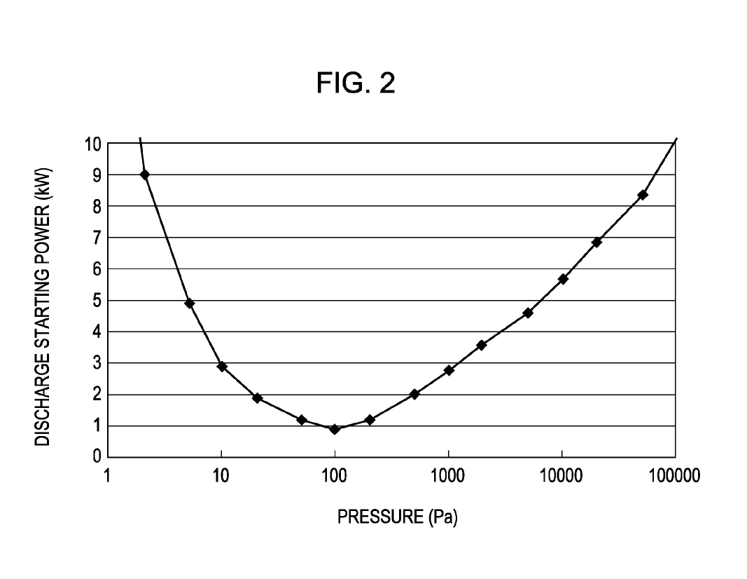

FIG. 2 shows the discharge starting power as a function of the internal pressure of the circular waveguide. For a normal maximum power of 3 kW, discharge may occur in the circular waveguide 112 at a pressure in the range of 10 to 1000 Pa. Thus, plasma may not be generated successfully in the plasma processing chamber 101. To reduce the pressure applied to the dielectric window 107 to one tenth or less of that in existing apparatuses, the pressure difference between the circular waveguide 112 and the plasma processing chamber 101 must be 10 kPa or less. Hence, the internal pressure of the circular waveguide in the plasma processing apparatus according to the present invention may be 10 Pa or less or in the range of 1 to 10 kPa.

The dielectric window in the plasma processing apparatus according to the present invention may be formed of a material that has a high mechanical strength and a small dielectric loss, allowing high microwave transmittance. Examples of the material include quartz, alumina (sapphire), aluminum nitride, and fluorocarbon polymers (registered trademark: Teflon). Heretofore, the thickness of the dielectric window has been determined in consideration of the mechanical strength resistant to atmospheric pressure. However, because the dielectric window according to the present invention is resistant to destruction, the thickness of the dielectric window, expressed by λₙ∈ᵣ^{-1/2}/4 (wherein λₙ denotes a natural wavelength of microwave and ∈ᵣ denotes a relative dielectric constant), may be selected to maximize the microwave transmittance.

The frequency of a microwave used in a microwave plasma processing apparatus according to the present invention may be in the range of 300 MHz to 3 THz. In particular, 1 to 10 GHz is effective, because the wavelength is almost the same as the thickness of the dielectric window 107.

The circular waveguide multislot antenna 108 of the microwave plasma processing apparatus according to the present invention may be formed of any electroconductive material, such as Al, Cu, or Ag/Cu-plated stainless steel, to minimize the propagation loss of a microwave. The inlet of the circular waveguide multislot antenna 108 used in the present invention may face any direction, provided that a microwave can efficiently be transmitted to a microwave propagation space in the circular waveguide multislot antenna 108. In other words, the direction of the inlet of the circular waveguide multislot antenna 108 may be parallel to or perpendicular to the H-plane, may be tangential to the propagation space, or may be such that microwaves are divided into left and right halves of the propagation space.

A microwave introducing device used in the present invention may be any device having a hollow structure, such as a cavity resonator, a coaxial coupling applicator, a coaxial waveguide-fed planar antenna, or a patch antenna, as well as the circular waveguide multislot antenna.

In the microwave plasma processing apparatus according to the present invention, a magnetic field generator may be used for lower-pressure processing. In this case, any magnetic field perpendicular to the electric field generated in the width direction of the slots can be used as the magnetic field. The magnetic field generator may be a permanent magnet, as well as a coil. When a coil is used, a water-cooling mechanism or another cooling apparatus such as an air-cooling apparatus may be used to prevent overheating.

Furthermore, a substrate to be treated may be irradiated with ultraviolet light. Any light source may be used, provided that the light source emits light that can be absorbed by a substrate to be treated or by gas adsorbed on the substrate. Examples of the light source include excimer lasers, excimer lamps, rare gas resonance line lamps, and low-pressure mercury lamps.

The internal pressure of a plasma processing chamber in a microwave plasma processing method according to the present invention may be in the range of 100 mPa to 1 kPa or in the range of 300 mPa to 300 Pa. In the plasma processing apparatus according to the present invention, a processing gas is appropriately selected to form a deposition film efficiently. Examples of the deposition film include insulating films, such as Si₃N₄, SiO₂, SiOF, Ta₂O₅, TiO₂, TiN, Al₂O₃, AlN, MgF₂, HfSiO, and HfAlO films; semiconductor films, such as a-Si, poly-Si, SiC, SiGe, and GaAs films; electroconductive films, such as Al, W, Mo, Ti, and Ta films; and carbon films.

The substrate 102 to be treated by the plasma processing apparatus according to the present invention may be a semiconductor, an electroconductive substrate, or an insulating substrate.

Examples of the electroconductive substrate include metals, such as Fe, Ni, Cr, Al, Mo, Au, Nb, Ta, V, Ti, Pt, and Pb, and alloys thereof, such as brass and stainless steel.

Examples of the insulating substrate include quartz, various SiO₂ glasses, inorganic substances, such as Si₃N₄, NaCl, KCl, LiF, CaF₂, BaF₂, Al₂O₃, AlN, and MgO, and films and sheets of organic substances, such as polyethylene, polyester, polycarbonate, cellulose acetate, polypropylene, polyvinyl chloride, polyvinylidene chloride, polystyrene, polyamide, and polyimide.

The direction of the processing gas inlets 105 in the plasma processing apparatus according to the present invention may be such that a processing gas flows through a plasma region generated in the vicinity of the dielectric window 107, is sufficiently supplied to the center of the plasma processing chamber 101, and then flows from the center to the periphery of the substrate surface. Hence, the processing gas inlets 105 may have such a structure that a processing gas is blown against the dielectric window 107.

A thin film deposited on a substrate may be formed by CVD using a generally known gas.

In the formation of a silicon semiconductor thin film, such as an a-Si, poly-Si, or SiC film, a silicon raw material gas introduced into the plasma processing chamber 101 through the processing gas inlets 105 is in a gaseous state or is easily gasified at normal temperature and pressure. Examples of the silicon raw material gas include inorganic silanes, such as SiH₄ and Si₂H₆; organic silanes, such as tetraethylsilane (TES), tetramethylsilane (TMS), dimethylsilane (DMS), dimethyldifluorosilane (DMDFS), and dimethyldichlorosilane (DMDCS); and halogenated silanes, such as SiF₄, Si₂F₆, Si₃F₈, SiHF₃, SiH₂F₂, SiCl₄, Si₂Cl₆, SiHCl₃, SiH₂Cl₂, SiH₃Cl, and SiCl₂F₂. The silicon raw material gas may be combined with an additive gas or a carrier gas, such as H₂, He, Ne, Ar, Kr, Xe, and Rn.

In the formation of a silicon compound thin film, such as a Si₃N₄ or SiO₂ film, a silicon raw material introduced into the plasma processing chamber 101 through the processing gas inlets 105 is in a gaseous state or is easily gasified at normal temperature and pressure. Examples of the silicon raw material include inorganic silanes, such as SiH₄ and Si₂H₆; organic silanes, such as tetraethoxysilane (TEOS), tetramethoxysilane (TMOS), octamethylcyclotetrasilane (OMCTS), dimethyldifluorosilane (DMDFS), and dimethyldichlorosilane (DMDCS); and halogenated silanes, such as SiF₄, Si₂F₆, Si₃F₈, SiHF₃, SiH₂F₂, SiCl₄, Si₂Cl₆, SiHCl₃, SiH₂Cl₂, SiH₃Cl, and SiCl₂F₂. The silicon raw material may be combined with a nitrogen raw material gas or an oxygen raw material gas, such as N₂, NH₃, N₂H₄, hexamethyldisilazane (HMDS), O₂, O₃, H₂O, NO, N₂O, and NO₂.

In the formation of a metallic thin film, such as an Al, W, Mo, Ti, or Ta film, a metallic raw material introduced into the plasma processing chamber 101 through the processing gas inlets 105 may be an organic metal or a halogenated metal. Examples of the organic metal include trimethylaluminum (TMAl), triethylaluminum (TEAl), triisobutylaluminum (TIBAl), dimethylaluminum hydride (DMAlH), and tungsten carbonyl (W(CO)₆). Other examples of the organic metal include molybdenum carbonyl (Mo(CO)₆), trimethylgallium (TMGa), triethylgallium (TEGa), tetraisopropoxytitanium (TIPOTi), and tantalum pentaethoxide (PEOTa). Examples of the halogenated metal include AlCl₃, WF₆, TiCl₃, and TaCl₅. The metallic raw material may be combined with an additive gas or a carrier gas, such as H₂, He, Ne, Ar, Kr, Xe, and Rn.

In the formation of a metallic compound thin film, such as an Al₂O₃, AlN, Ta₂O₅, TiO₂, TiN, or WO₃ film, a metallic raw material introduced into the plasma processing chamber 101 through the processing gas inlets 105 may be an organic metal or a halogenated metal. Examples of the organic metal include trimethylaluminum (TMAl), triethylaluminum (TEAl), triisobutylaluminum (TIBAl), dimethylaluminum hydride (DMAlH), and tungsten carbonyl (W(CO)₆). Other examples of the organic metal include molybdenum carbonyl (Mo(CO) 6), trimethylgallium (TMGa), triethylgallium (TEGa), tetraisopropoxytitanium (TIPOTi), and tantalum pentaethoxide (PEOTa). Examples of the halogenated metal include AlCl₃, WF₆, TiCl₃, and TaCl₅. The silicon raw material may be combined with an oxygen raw material gas or a nitrogen raw material gas, such as O₂, O₃, H₂O, NO, N₂O, NO₂, N₂, NH₃, N₂H₄, and hexamethyldisilazane (HMDS).

In the formation of a carbonaceous thin film, such as a graphite, carbon nanotube (CNT), diamond-like carbon (DLC), or diamond film, a raw material introduced into the plasma processing chamber 101 through the processing gas inlets 105 may be any carbonaceous material. Examples of the carbonaceous material include saturated hydrocarbons, such as CH₄, C₂H₆, and C₃H₈; unsaturated hydrocarbons, such as C₂H₄, C₃H₆, C₂H₂, and C₃H₄; aromatic hydrocarbons, such as C₆H₆; alcohols, such as CH₃OH and CH₂H₅OH; ketones, such as (CH₃)₂CO; aldehydes, such as CH₃CHO; carboxylic acids, such as HCOOH and CH₃COOH.

In etching of the substrate surface, an etching gas introduced into the plasma processing chamber 101 through the processing gas inlets 105 may be F₂, CF₄, CH₂F₂, C₂F₆, C₃F₈, C₄F₈, CF₂Cl₂, SF₆, NF₃, Cl₂, CCl₄, CH₂Cl₂, or C₂Cl₆. In ashing removal of an organic component, such as a photoresist, on the substrate surface, an ashing gas introduced into the plasma processing chamber 101 through the processing gas inlets 105 may be O₂, O₃, H₂O, NO, N₂O, NO₂, N₂, or H₂.

The microwave plasma processing apparatus according to the present invention can also be used in various surface reforming treatments by appropriately selecting the processing gas. For example, a substrate or a surface layer of Si, Al, Ti, Zn, or Ta may be oxidized or nitrided. Furthermore, the substrate or the surface layer may be doped with B, As, or P. A film-forming technique used in the present invention may also be used in a cleaning method. Oxides, organic substances, or heavy metals may be cleaned by the film-forming technique.

In surface oxidation of a substrate, an oxidizing gas introduced into the plasma processing chamber 101 through the processing gas inlets 105 may be O₂, O₃, H₂O, NO, N₂O, or NO₂. In surface nitriding of a substrate, a nitriding gas introduced into the plasma processing chamber 101 through the processing gas inlets 105 may be N₂, NH₃, N₂H₄, or hexamethyldisilazane (HMDS). In cleaning of an organic substance on the substrate surface, a cleaning/ashing gas introduced into the plasma processing chamber 101 through the processing gas inlets 105 may be O₂, O₃, H₂O, NO, N₂O, NO₂, N₂, or H₂. In cleaning of an inorganic substance on the substrate surface, a cleaning gas introduced into the plasma processing chamber 101 through the processing gas inlets 105 may be F₂, CF₄, CH₂F₂, C₂F₆, C₄F₈, CF₂Cl₂, SF₆, or NF₃. In ashing removal of an organic component, such as a photoresist, on the substrate surface, a cleaning/ashing gas introduced into the plasma processing chamber 101 through the processing gas inlets 105 may be O₂, O₃, H₂O, NO, N₂O, NO₂, N₂, or H₂.

### EXAMPLES

A microwave plasma processing apparatus according to the present invention will be further described with examples. However, the present invention is not limited to these examples.

### Example 1

A microwave plasma processing apparatus illustrated in FIG. 1 was used for the ashing of a cured photoresist. A dielectric window 107 was an aluminum nitride disk having a diameter of 380 mm and a thickness of 10.5 mm.

A substrate 102 was a silicon (Si) substrate (diameter 300 mm) used immediately after the implantation of 7×10¹⁴ cm⁻² of B⁺ ions. First, the Si substrate 102 was placed on a substrate supporting portion 103 and was heated to 250° C. with a heater (substrate temperature regulator) 104. A plasma processing chamber 101 was evacuated to 10⁻¹ Pa using an evacuation system (not shown). An oxygen gas containing 5% SF₆ was introduced into the plasma processing chamber 101 through plasma processing gas inlets 105 at a flow rate of 2 standard liters per minute (slm). A conductance valve (not shown) of the evacuation system (not shown) was then controlled to maintain the internal pressure of the plasma processing chamber 101 at 400 Pa. Microwaves having an electric power of 2.5 kW were transmitted from a 2.45 GHz microwave power supply to the plasma processing chamber 101 via a circular waveguide multislot antenna 108. Plasma was generated in the plasma processing chamber 101. The oxygen gas containing SF₆ introduced through the plasma processing gas inlets 105 was excited, decomposed, and was allowed to react to yield fluorine or oxygen atoms in the plasma processing chamber 101. The fluorine or oxygen atoms flowed toward the Si substrate 102. The fluorine or oxygen atoms reacted with and vaporized a photoresist cured on the substrate 102. The aluminum nitride window 107 and a sealant thereof had no abnormality after 1000 running tests.

### Example 2

A microwave plasma processing apparatus illustrated in FIG. 1 was used to nitride the surface of an ultrathin oxide film. A dielectric window 107 was a silicon oxide disk having a diameter of 340 mm and a thickness of 16 mm. A substrate 102 was a silicon (Si) substrate (diameter 200 mm) on which an oxide film having a thickness of 1.4 nm was deposited. First, the Si substrate 102 was placed on a substrate supporting portion 103 and was heated to 150° C. with a heater 104. A plasma processing chamber 101 was evacuated to 10⁻⁵ Pa using an evacuation system (not shown). A nitrogen gas and a helium gas were introduced into the plasma processing chamber 101 through plasma processing gas inlets 105 at flow rates of 50 and 450 standard cubic centimeters per minute (sccm), respectively.

A conductance valve (not shown) of the evacuation system (not shown) was then controlled to maintain the internal pressure of the plasma processing chamber 101 at 30 Pa. Microwaves having an electric power of 1.5 kW were transmitted from a 2.45 GHz microwave power supply to the plasma processing chamber 101 via a circular waveguide multislot antenna 108. Plasma was generated in the plasma processing chamber 101. The nitrogen gas introduced through the plasma processing gas inlets 105 was excited, decomposed, and was allowed to react to yield nitrogen ions or atoms in the plasma processing chamber 101. The nitrogen ions or atoms nitrided the oxide film of the Si substrate 102. The silicon oxide window 107 and a sealant thereof had no abnormality after 1000 running tests.

### Example 3

A microwave plasma processing apparatus illustrated in FIG. 1 was used to directly nitride a Si substrate. A dielectric window 107 was a silicon oxide disk having a diameter of 330 mm and a thickness of 16 mm. A substrate 102 was a bare silicon (Si) substrate (diameter 200 mm). First, the Si substrate 102 was placed on a substrate supporting portion 103 and was heated to 150° C. with a heater 104. A plasma processing chamber 101 was evacuated to 10⁻⁵ Pa using an evacuation system (not shown). A nitrogen gas was introduced into the plasma processing chamber 101 through plasma processing gas inlets 105 at a flow rate of 500 sccm.

A conductance valve (not shown) of the evacuation system (not shown) was then controlled to maintain the internal pressure of the plasma processing chamber 101 at 20 Pa. Microwaves having an electric power of 1.5 kW were transmitted from a 2.45 GHz microwave power supply to the plasma processing chamber 101 via a circular waveguide multislot antenna 108. Plasma was generated in the plasma processing chamber 101. The nitrogen gas introduced through the plasma processing gas inlets 105 was excited, decomposed, and was allowed to react to yield nitrogen ions or atoms in the plasma processing chamber 101. The nitrogen ions or atoms directly nitrided the surface of the Si substrate 102. The silicon oxide window 107 and a sealant thereof had no abnormality after 1000 running tests.

### Example 4

A microwave plasma processing apparatus illustrated in FIG. 1 was used to form a silicon nitride film for protecting a semiconductor element. A dielectric window 107 was a silicon oxide disk having a diameter of 380 mm and a thickness of 16 mm.

A substrate 102 was a P-type single crystal Si substrate (diameter 300 mm, plane orientation <100>, resistivity 10 Ωcm) including an interlayer SiO₂ film. An Al wiring pattern (line and space 0.5 μm) was formed on the Si substrate. First, the Si substrate 102 was placed on a substrate supporting portion 103. A plasma processing chamber 101 was evacuated to 10⁻⁵ Pa using an evacuation system (not shown). The Si substrate 102 was heated to 300° C. with a heater 104 and was hold at this temperature. A nitrogen gas and a monosilane gas were introduced into the plasma processing chamber 101 through plasma processing gas inlets 105 at flow rates of 600 and 150 sccm, respectively. A conductance valve (not shown) of the evacuation system (not shown) was then controlled to maintain the internal pressure of the plasma processing chamber 101 at 3 Pa. Microwaves having an electric power of 3.0 kW were transmitted from a 2.45 GHz microwave power supply (not shown) to the plasma processing chamber 101 via a circular waveguide multislot antenna 108. Plasma was generated in the plasma processing chamber 101. The nitrogen gas introduced through the plasma processing gas inlets 105 was excited and decomposed to yield nitrogen atoms in the plasma processing chamber 101. The nitrogen atoms flowed toward the Si substrate 102. The nitrogen atoms reacted with the monosilane gas, forming a silicon nitride film having a thickness of 1.0 μm on the Si substrate 102. The silicon oxide window 107 and a sealant thereof had no abnormality other than film deposition after 1000 running tests.

### Example 5

A microwave plasma processing apparatus illustrated in FIG. 1 was used to form a silicon oxide film for interlayer insulating of semiconductor elements. A dielectric window 107 was a silicon oxide disk having a diameter of 370 mm and a thickness of 16 mm.

A substrate 102 was a P-type single crystal Si substrate (diameter 300 mm, plane orientation <100>, resistivity 10 Ωcm) on which an Al wiring pattern (line and space 0.5 μm) was formed. First, the Si substrate 102 was placed on a substrate supporting portion 103. A plasma processing chamber 101 was evacuated to 10⁻⁵ Pa using an evacuation system (not shown). The Si substrate 102 was heated to 300° C. with a heater 104 and was hold at this temperature. An oxygen gas and a monosilane gas were introduced into the plasma processing chamber 101 through plasma processing gas inlets 105 at flow rates of 400 and 200 sccm, respectively.

A conductance valve (not shown) of the evacuation system (not shown) was then controlled to maintain the internal pressure of the plasma processing chamber 101 at 3 Pa. An electric power of 300 W was applied to the substrate supporting portion 103 with a 2 MHz high frequency application unit. Microwaves having an electric power of 2.5 kW were transmitted from a 2.45 GHz microwave power supply to the plasma processing chamber 101 via a circular waveguide multislot antenna 108. Plasma was generated in the plasma processing chamber 101. The oxygen gas introduced through the plasma processing gas inlets 105 was excited and decomposed to yield active species in the plasma processing chamber 101. The active species flowed toward the Si substrate 102. The active species reacted with the monosilane gas, forming a silicon oxide film having a thickness of 0.8 μm on the Si substrate 102. Ionic species accelerated by a radio frequency (RF) bias bombard the silicon oxide film formed on the Al wiring pattern, thus improving the flatness. The silicon oxide window 107 and a sealant thereof had no abnormality.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims the benefit of Japanese Application No. 2006-345795 filed Dec. 22, 2006, which is hereby incorporated by reference herein in its entirety.

What is claimed is:

1. A plasma processing apparatus that includes a vacuum vessel having a dielectric window, a first exhaust unit configured to evacuate the vacuum vessel, and a microwave introducing portion for introducing a microwave into the vacuum vessel through the dielectric window, the plasma processing apparatus further comprising:
a second exhaust unit configured to evacuate a closed space of the microwave introducing portion side of the dielectric window.

2. The plasma processing apparatus according to claim 1, wherein the second exhaust unit reduces the internal pressure of the microwave introducing portion to 10 Pa or less.

3. The plasma processing apparatus according to claim 1, wherein the second exhaust unit reduces the internal pressure of the microwave introducing portion to be in the range of 1 to 10 kPa.

4. The plasma processing apparatus according to claim 1, wherein the microwave introducing portion is a circular waveguide.

5. The plasma processing apparatus according to claim 1, wherein the dielectric window is made of quartz.

6. The plasma processing apparatus according to claim 1, wherein the first exhaust unit communicates with the second exhaust unit via an equalizing valve.

7. The plasma processing apparatus according to claim 1, wherein the second exhaust unit is an equalizing valve that communicates the closed space with the first exhaust unit.
